(19) United States
(12) Patent Application Publication
(10) Pub. No.: US 2025/0183195 A1
(43) Pub. Date: Jun. 5, 2025

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/966,390

(22) Filed: Dec. 3, 2024

(30) Foreign Application Priority Data
Dec. 5, 2023 (KR) 10-2023-0174934

(51) Int. Cl. H01L 23/00; H01L 23/498; H01L 23/538; H01L 25/065; H01L 25/18; H10B 80/00

(52) U.S. Cl. CPC H01L 23/562; H01L 23/5385; H01L 25/18; H01L 23/49816; H01L 25/0657; H01L 2225/06513; H01L 2225/06541; H01L 2225/06565; H10B 80/00

(57) ABSTRACT

A semiconductor package includes a package substrate, an interposer disposed on the package substrate, the interposer including a first surface and a second surface opposite to the first surface, a first semiconductor device mounted on the second surface of the interposer, a second semiconductor device disposed on the second surface and spaced apart from the first semiconductor device in a first horizontal direction that is parallel to the second surface, and a warpage prevention structure disposed on the first surface of the interposer at a position on the first surface that corresponds to a position between the first semiconductor device and the second semiconductor device on the second surface of the interposer and that vertically overlaps the first semiconductor device and the second semiconductor device.

### CROSS-REFERENCE TO RELATED APPLICATION

This application is based on and claims priority under 35 U.S.C. § 119 to Korean Patent Application No. 10-2023-0174934, filed on Dec. 5, 2023, in the Korean Intellectual Property Office, the disclosure of which is incorporated by reference herein in its entirety.

### BACKGROUND

The present disclosure relates to a semiconductor package, and more particularly, to a semiconductor package including an interposer substrate.

As the electronics industry advances rapidly and the demands of users increase, electronic devices are becoming more smaller and lighter. As electronic devices become smaller and lighter, semiconductor packages are being made smaller and lighter, and moreover, semiconductor packages need high performance, large capacity, and high reliability. Based on such trends, semiconductor packages where an interposer substrate is mounted on a package substrate and a plurality of semiconductor chips are then stacked spaced apart from one another on the interposer substrate in a horizontal direction have been proposed.

### SUMMARY

It is an aspect to provide a semiconductor package in which warpage is reduced and a thermal characteristic is enhanced.

According to an aspect of one or more embodiments, there is provided a semiconductor package comprising a package substrate; an interposer disposed on the package substrate, the interposer including a first surface and a second surface opposite to the first surface; a first semiconductor device mounted on the second surface of the interposer; a second semiconductor device disposed on the second surface and spaced apart from the first semiconductor device in a first horizontal direction that is parallel to the second surface; and a warpage prevention structure disposed on the first surface of the interposer at a position on the first surface that corresponds to a position between the first semiconductor device and the second semiconductor device on the second surface of the interposer and that vertically overlaps the first semiconductor device and the second semiconductor device.

According to another aspect of one or more embodiments, there is provided a semiconductor package comprising a package substrate; an interposer disposed on the package substrate, the interposer including a first surface and a second surface opposite to the first surface; a pair of first memory devices mounted on the second surface of the interposer and disposed spaced apart from each other in a first horizontal direction that is parallel to the second surface; a pair of non-memory devices disposed spaced apart from the pair of first memory devices in a second horizontal direction perpendicular to the first horizontal direction; and a first warpage prevention structure disposed on the first surface of the interposer at a position that corresponds to a position between the pair of first memory devices on the second surface of the interposer and that vertically overlaps each of the pair of first memory devices.

According to yet another aspect of one or more embodiments, there is provided a semiconductor package comprising a package substrate; an interposer including an interposer substrate and a plurality of interposer through vias passing through the interposer substrate, the interposer substrate being disposed on the package substrate, and the interposer including a first surface and a second surface opposite to the first surface; a plurality of interposer connection terminals disposed on the first surface of the interposer; a pair of first memory devices mounted on the second surface of the interposer and disposed spaced apart from each other in a first horizontal direction that is parallel to the second surface; a pair of non-memory devices mounted on the second surface of the interposer and disposed spaced apart from the pair of first memory devices in a second horizontal direction perpendicular to the first horizontal direction; a pair of second memory devices mounted on the second surface of the interposer and disposed spaced apart from the pair of first memory devices with the pair of non-memory devices therebetween in the second horizontal direction; a package molding layer that seals the pair of first memory devices, the pair of non-memory devices, and the pair of second memory devices; a first warpage prevention structure disposed on the first surface of the interposer at a position on the first surface that corresponds to a position between the pair of first memory devices on the second surface of the interposer and that vertically overlaps each of the pair of first memory devices and the package molding layer; and a second warpage prevention structure disposed on the first surface of the interposer at a position on the first surface that corresponds to a position between the pair of second memory devices on the second surface of the interposer and that vertically overlaps each of the pair of second memory devices and the package molding layer.

### BRIEF DESCRIPTION OF THE DRAWINGS

Embodiments will be more clearly understood from the following detailed description taken in conjunction with the accompanying drawings in which:

FIG. 1 is a perspective view of a semiconductor package according to an embodiment;

FIG. 2 is a plan view of a semiconductor package according to an embodiment;

FIG. 3 is a cross-sectional view taken along line A-A′ in the plan view of FIG. 2;

FIG. 4 is an enlarged view of a region CX1 in the cross-sectional view of FIG. 3;

FIG. 5 is a cross-sectional view taken along line B-B′ in the plan view of FIG. 2;

FIG. 6 is a cross-sectional view of a semiconductor package according to an embodiment;

FIG. 7 is an enlarged view of a region CX2 in the cross-sectional view of FIG. 6;

FIG. 8 is an enlarged view of a semiconductor package according to an embodiment;

FIG. 9 is a plan view of a semiconductor package according to an embodiment;

FIG. 10 is a cross-sectional view taken along line C-C′ in the plan view of FIG. 9;

FIGS. 11 to 13 are cross-sectional views illustrating a method of manufacturing a semiconductor package, according to an embodiment;

FIG. 14 is a schematic block diagram illustrating an example of a memory system including a semiconductor package, according to an embodiment; and

FIG. 15 is a schematic block diagram illustrating an example of an information processing system including a semiconductor package, according to an embodiment.

### DETAILED DESCRIPTION

Aspects are not limited to the aforesaid aspects, but other aspects not described herein will be clearly understood by those of ordinary skill in the art from descriptions below.

Hereinafter, various embodiments will be described in detail with reference to the accompanying drawings. However, embodiments are not limited to the following illustrated embodiments but may be embodied in different forms. The following embodiments are provided for sufficiently providing the scope of the present disclosure to those of ordinary skill in the art. As used in this specification, the term “a pair” includes within its scope two. As used within this specification, the phrase “at least one of A, B, or C” includes within its scope “only A”, “only B”, “only C”, “A and B”, “B and C”, “A and C” and “A, B, and C”.

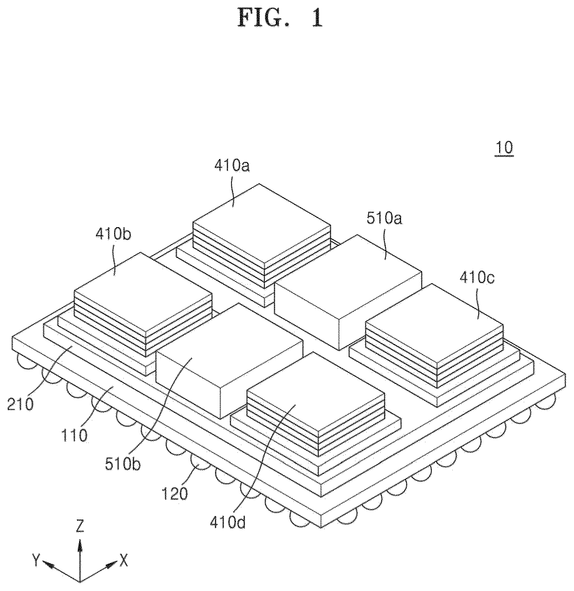

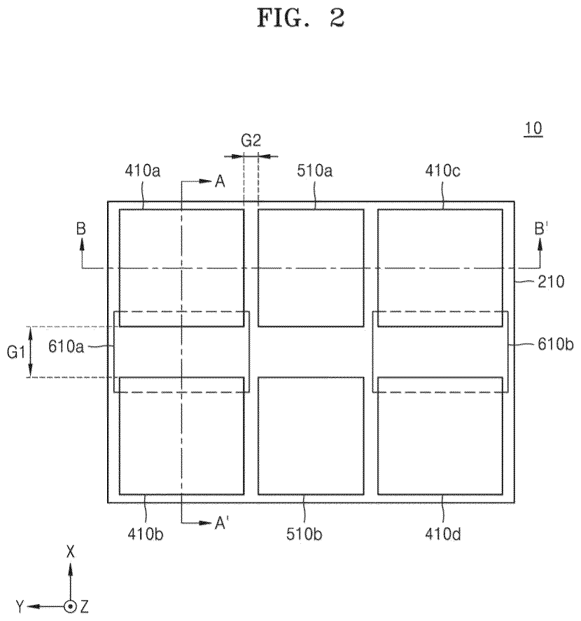

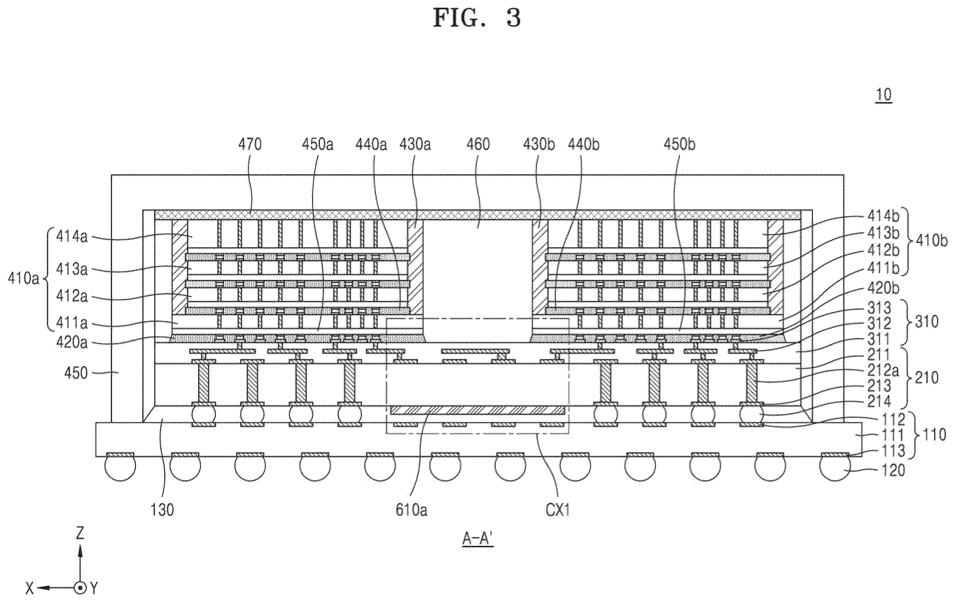

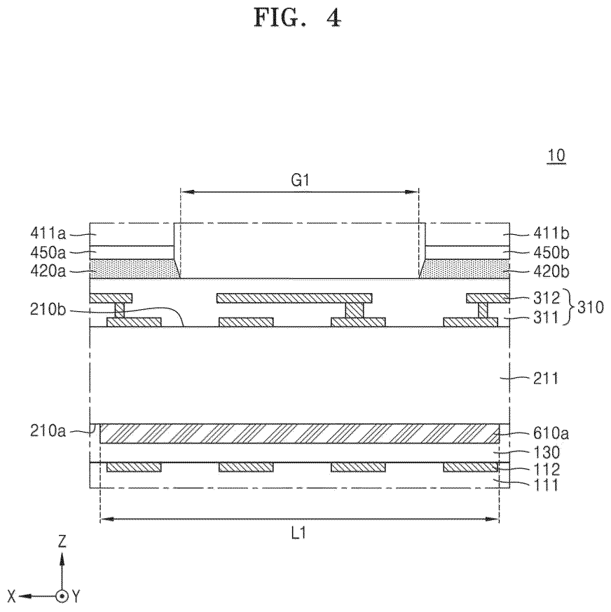

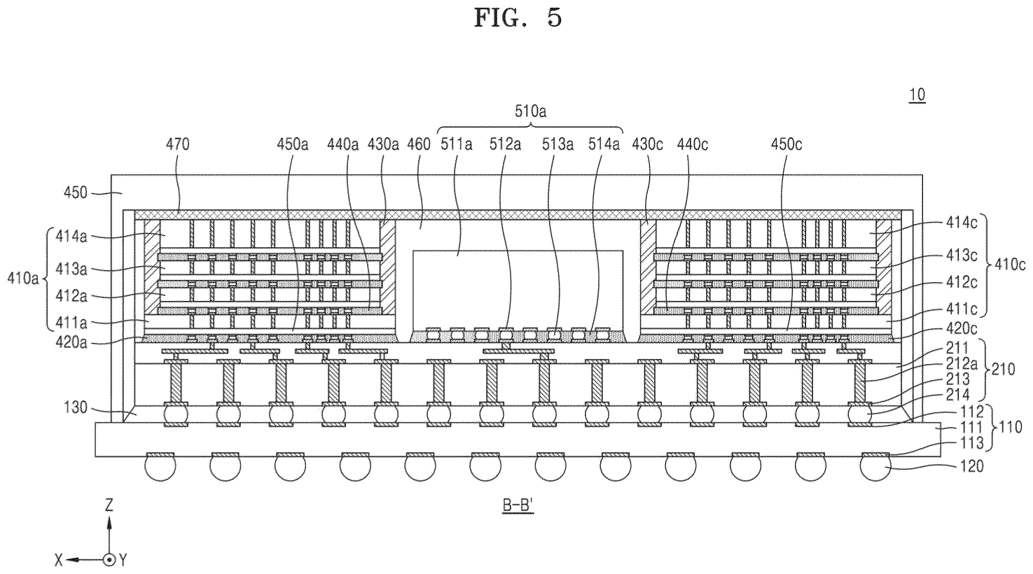

FIG. 1 is a perspective view of a semiconductor package 10 according to an embodiment, and FIG. 2 is a plan view of the semiconductor package 10 according to an embodiment. FIG. 3 is a cross-sectional view taken along line A-A′ of FIG. 2, and FIG. 4 is an enlarged view of a region CX1 of FIG. 3. FIG. 5 is a cross-sectional view taken along line B-B′ of FIG. 2.

Referring to FIGS. 1 to 5, the semiconductor package 10 may include a package substrate 110, a plurality of external connection terminals 120, a first under-fill 130, an interposer 210, an interposer redistribution structure 310, a plurality of memory devices 410a to 410d, and a plurality of non-memory devices 510a and 510b. In this case, the plurality of memory devices 410a to 410d may include a first memory device 410a, a second memory device 410b, a third memory device 410c, and a fourth memory device 410d, and the plurality of non-memory devices 510a and 510b may include a first non-memory device 510a and a second non-memory device 510b. The plurality of memory devices 410a to 410d and the plurality of non-memory devices 510a and 510b may each be referred to as a semiconductor device.

According to an embodiment, the package substrate 110 may include a substrate body 111, a plurality of substrate upper pads 112 disposed on an upper surface of the substrate body 111, and a plurality of substrate lower pads 113 disposed on a lower surface of the substrate body 111. The package substrate 110 may be a supporting substrate with the interposer 210 and the plurality of memory devices 410a to 410d mounted thereon. The package substrate 110 may be a semiconductor package substrate including a printed circuit board (PCB), a ceramic substrate, a glass substrate, and/or a tape wiring substrate.

The substrate body 111 may include a different material, based on the kind of package substrate 110. For example, when the package substrate 110 is a PCB, the substrate body 111 may have a structure in which a wiring layer is stacked on one surface or both surfaces of a copper foil stack plate or a copper foil stack plate. A lower protection layer and an upper protection layer each coated with a solder resist may be respectively formed on a lower surface and an upper surface of the substrate body 111.

The external connection terminals 120 configured to electrically connect the semiconductor package 10 to an external device may be disposed on the substrate lower pads 113. The external connection terminals 120 may include, for example, a solder ball. Interposer connection terminals 214 respectively electrically connected to a plurality of first through vias 212a may be disposed on the substrate upper pads 112.

The substrate lower pad 113 and the substrate upper pads 112 may form an electrical path which connects a lower surface of the package substrate 110 to an upper surface of the package substrate 110. The substrate lower pads 113 and the substrate upper pad 112 may include a metal material, and for example, may include at least one metal or two or more metals of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C).

According to an embodiment, the external connection terminals 120 may include tin (Sn), indium (In), bismuth (Bi), antimony (Sb), copper (Cu), silver (Ag), zinc (Zn), lead (Pb), and/or an alloy thereof. For example, the external connection terminals 120 may have a spherical or ball shape including an alloy including Sn (for example, Sn—Ag—Cu).

According to an embodiment, the first under-fill 130 may surround the interposer connection terminals 214 and a plurality of warpage prevention structures, for example, a first warpage prevention structure 610a and a second warpage prevention structure 610b. The first under-fill 130 may include, for example, at least one of an insulating polymer or epoxy resin. For example, in an embodiment, a material included in the first under-fill 130 may include an epoxy molding compound (EMC).

The interposer 210 may include an interposer substrate 211, a plurality of first through vias 212a, a plurality of interposer pads 213, and a plurality of interposer connection terminals 214.

The first memory device 410a, the second memory device 410b, the third memory device 410c, the first non-memory device 510a, and the second non-memory device 510b may be mounted on the interposer 210. The interposer 210 is illustrated as a silicon interposer substrate including a through silicon via (TSV), but embodiments are not limited to a silicon interposer substrate or an interposer substrate including a through silicon via (TSV). For example, in some embodiments, the interposer 210 may be a redistribution substrate.

The interposer substrate 211 may include a first surface 210a facing the package substrate 110 and a second surface 210b which faces the plurality of semiconductor devices 410a to 410d, 510a, and 510b and is opposite to the first surface 210a (see, e.g., FIG. 4). The interposer substrate 211 may include a semiconductor element, such as silicon (Si) or germanium (Ge), or a compound semiconductor such as silicon carbide (SiC), gallium arsenide (GaAs), indium arsenide (InAs), and indium phosphide (InP).

Herein, a direction which is parallel to the second surface 210b of the interposer substrate 211 and in which the first memory device 410a and the second memory device 410b are disposed spaced apart from each other in parallel may be defined as a first horizontal direction (e.g., an X direction). A direction which is parallel to the second surface 210b of the interposer substrate 211 and is perpendicular to the first horizontal direction (e.g., the X direction) may be defined as a second horizontal direction (e.g., a Y direction). A direction which is perpendicular to the second surface 210b of the interposer substrate 211 and is perpendicular to the first horizontal direction (the X direction) and the second horizontal direction (the Y direction) may be defined as a vertical direction (e.g., a Z direction).

The first through vias 212a may be a TSV which passes through the interposer substrate 211 in the vertical direction (the Z direction). The first through vias 212a may provide an electrical path which connects the interposer pad 213 of the interposer 210 to a conductive redistribution pattern 312 of the interposer redistribution structure 310. That is, the first through vias 212a may electrically connect the package substrate 110 to the interposer redistribution structure 310.

The first through vias 212a may each include a conductive plug and a barrier layer surrounding the conductive plug. The conductive plug may include, for example, tungsten (W), Ti, Al, or Cu. The conductive plug may be formed by a plating process, a physical vapor deposition (PVD) process, or a chemical vapor deposition (CVD) process. The barrier layer may include an insulating barrier layer or/and a conductive barrier layer. The insulating barrier layer may include oxide, nitride, carbide, a polymer, or a combination thereof. The conductive barrier layer may be disposed between the insulating barrier layer and the conductive plug. The conductive barrier layer may include, for example, a metal compound such as tungsten nitride (WN), titanium nitride (TiN), or tantalum nitride (TaN). The barrier layer may be formed by a PVD process or a CVD process.

The interposer pads 213 may be disposed on the first surface 210a of the interposer 210. With respect to a plane, the interposer pads 213 may be disposed to surround the first and second warpage prevention structures 610a and 610b attached on the first surface 210a of the interposer 210. For example, in some embodiments, the interposer pads 213 may be disposed on all sides of the first and second warpage prevention structures 610a and 610b in plan view. The interposer pads 213 may be disposed to be connected to a lower end portion of the first through vias 212a, and the number of interposer pads 213 may correspond to the number of first through vias 212a. The interposer pads 213 may include a metal material, and the metal material may include W, Ti, Al, or Cu.

The interposer connection terminals 214 may be disposed between the interposer pads 213 of the interposer 210 sand the substrate upper pads 112 of the package substrate 110. The interposer connection terminals 214 may be configured to electrically connect the interposer 210 to the package substrate 110. The number of interposer connection terminals 214 may correspond to the number of interposer pads 213. The interposer connection terminals 214 may include Sn, In, Bi, Sb, Cu, Ag, Zn, Pb, and/or an alloy thereof. For example, the interposer connection terminals 214 may have a spherical or ball shape including an alloy including Sn (for example, Sn—Ag—Cu).

The interposer redistribution structure 310 may be disposed on the second surface 210b of the interposer 210 and may include a redistribution insulation layer 311, a conductive redistribution pattern 312, and a plurality of connection pads 313. The redistribution insulation layer 311 may be disposed on the second surface 210b of the interposer substrate 211 and may include silicon oxide or silicon nitride. The conductive redistribution pattern 312 may electrically connect the first memory device 410a to the second memory device 410b. As illustrated in FIG. 3, the conductive redistribution pattern 312 may electrically connect the first and second memory devices 410a and 410b to the interposer 210. Furthermore, the conductive redistribution pattern 312 may electrically connect the third and fourth memory devices 410c and 410d and the first and second non-memory devices 510a and 510b to the interposer 210. The conductive redistribution pattern 312 may be configured with a one or more-layer metal wiring and a contact via. The contact via may electrically connect the one or more-layer metal wirings with each other, or may electrically connect the one or more-layer metal wiring to the connection pads 313. The conductive redistribution pattern 312 may electrically and physically connect the first through vias 212a to the connection pads 313. The conductive redistribution pattern 312 and the connection pads 313 may include a metal material, and for example, may include at least one metal or two or more metals of Cu, Al, Ni, Ag, Au, Pt, Sn, Pb, Ti, Cr, Pd, In, Zn, and C.

The plurality of semiconductor devices 410a to 410d, 510a, and 510b may be disposed on the interposer redistribution structure 310. The plurality of semiconductor devices 410a to 410d, 510a, and 510b may include the first memory device 410a, the second memory device 410b, the third memory device 410c, the fourth memory device 410d, the first non-memory device 510a, and the second non-memory device 510b.

In this case, as illustrated in FIG. 2, the first memory device 410a and the second memory device 410b may be arranged spaced apart from each other in the first horizontal direction (the X direction), and the third memory device 410c and the fourth memory device 410d may be arranged spaced apart from each other in the first horizontal direction (the X direction). The first non-memory device 510a and the second non-memory device 510b may be arranged spaced apart from each other in the first horizontal direction (the X direction).

Each of the first memory device 410a and the second memory device 410b may include a plurality of integrated circuit devices which are stacked in a vertical direction. For example, as illustrated in FIG. 3, the first memory device 410a and the second memory device 410b may include, respectively, first integrated circuit devices 411a and 411b, second integrated circuit devices 412a and 412b, third integrated circuit devices 413a and 413b, and fourth integrated circuit devices 414a and 414b, which are stacked in the vertical direction. For example, the first memory device 410a may include the first integrated circuit device 411a, the second integrated circuit device 412a, the third integrated circuit device 413a, and the fourth integrated circuit device 414a, which are stacked in the vertical direction, and the second memory device 410b may include the first integrated circuit device 411b, the second integrated circuit device 412b, the third integrated circuit device 413b, and the fourth integrated circuit device 414b, which are stacked in the vertical direction.

In embodiments, each of the first memory device 410a and the second memory device 410b may be a stack-type memory device. For example, each of the first memory device 410a and the second memory device 410b may have a three-dimensional (3D) memory structure where a plurality of chips are stacked. For example, each of the first memory device 410a and the second memory device 410b may be implemented based on high bandwidth memory (HBM) or hybrid memory cube (HMC) standard. In this case, the first integrated circuit devices 411a and 411b disposed in a lowermost layer may function as a buffer die, and each of the second to fourth integrated circuit devices 412a, 412b, 413a, 413b, 414a, and 414b may function as a core die. For example, the buffer die may be referred to as an interface die, a base die, a logic die, or a master die, and the core die may be referred to as a memory die or a slave die. In FIG. 3, the first memory device 410a and the second memory device 410b are illustrated as including three core dies, but embodiments are not limited thereto and, in some embodiment, the number of core dies may be variously changed. For example, the first memory device 410a may include four, eight, twelve, or sixteen core dies.

The third memory device 410c illustrated in FIG. 5 may include the first integrated circuit device 411c disposed in a lowermost layer and the second to fourth integrated circuit devices 412c, 413c, and 414c sequentially stacked on the first integrated circuit device 411c. In this case, the first to fourth integrated circuit devices 411c, 412c, 413c, and 414c included in the third memory device 410c may be substantially the same as or similar to the first to fourth integrated circuit devices 411a, 411b, 412a, 412b, 413a, 413b, 414a, and 414b included respectively in the first memory device 410a and the second memory device 410b.

Second under-fills 420a and 420b surrounding connection bumps and the connection pads 323 may be respectively disposed between the first memory device 410a and the interposer 210 and between the second memory device 410b and the interposer 210. The second under-fills 420a and 420b may include, for example, at least one of an insulating polymer and epoxy resin. For example, in an embodiment, a material included in the second under-fills 420a and 420b may include an EMC.

According to an embodiment, the third memory device 410c and the fourth memory device 410d may include the same configuration and function as that of the first memory device 410a and the second memory device 410b and thus repeated description thereof is omitted for conciseness.

As illustrated in FIG. 5, the first non-memory device 510a may include a chip body 511a, a plurality of chip pads 512a, a plurality of chip connection terminals 513a, and a third under-fill 514a. The chip body 511a may include a logic chip. In this case, the logic chip may be, for example, a system on chip, a central processing unit (CPU) chip, a graphics processing unit (GPU) chip, or an application processor (AP) chip. The first non-memory device 510a may execute applications supported by the semiconductor package 10 by using the first memory device 410a and the second memory device 410b. For example, the first non-memory device 510a may execute specialized arithmetic operations by using at least one of a CPU, an AP, a GPU, a neural processing unit (NPU), a tensor processing unit (TPU), a vision processing unit (VPU), an image signal processor (ISP), or a digital signal processor (DSP).

The chip pads 512a may be used to electrically connect the first non-memory device 510a to the other element. The chip pads 512a may include, for example, a conductive material including Cu, Al, Ag, Au, W, or Ti, or a combination thereof. The chip connection terminals 513a may be attached on the chip pads 512a and may electrically connect the first non-memory device 510a to the interposer redistribution structure 310. The first non-memory device 510a may be mounted on the interposer 210 through the chip connection terminals 513a attached on the chip pads 512a. The chip connection terminals 513a may be, for example, a solder ball. According to an embodiment, the chip connection terminals 513a may include Sn, In, Bi, Sb, Cu, Ag, Zn, or Pb, and/or an alloy thereof. For example, the chip connection terminal 513a may have a spherical or ball shape including an alloy including Sn (for example, Sn—Ag—Cu).

A third under-fill 514a may be disposed between the chip body 511a and the interposer redistribution structure 310. The third under-fill 514a may surround the chip connection terminals 513a. The third under-fill 514a may include, for example, at least one of an insulating polymer and epoxy resin. For example, a material included in the third under-fill 514a may include an EMC.

According to an embodiment, the second non-memory device 510b may include the same configuration and function as that of the first non-memory device 510a and thus repeated description thereof is omitted for conciseness.

The first memory device 410a and the second memory device 410b may be mounted spaced apart from each other on the interposer redistribution structure 310 of the interposer 210 in the first horizontal direction (the X direction). The first memory device 410a and the second memory device 410b may be electrically connected to each other through the conductive redistribution pattern 312 of the interposer redistribution structure 310. The first memory device 410a may be mounted on the interposer 210 through connection bumps disposed on a lower surface of the first memory device 410a, and the second memory device 410b may be mounted on the interposer 210 through connection bumps disposed on a pad of the second memory device 410b.

According to an embodiment, the semiconductor package 10 may further include molding layers 430a and 430b surrounding the second to fourth integrated circuit devices 412a, 413a, and 414a of the first memory device 410a and the second to fourth integrated circuit devices 412b, 413b, and 414b of the second memory device 410b. In some embodiments, the first integrated circuit devices 411a and 411b may be greater in width than the second to fourth integrated circuit devices 412a, 412b, 413a, 413b, 414a, and 414b in a lateral direction (the X direction and/or the Y direction), and thus, the first integrated circuit devices 411a and 411b may each include a region which does not overlap the second to fourth integrated circuit devices 412a, 412b, 413a, 413b, 414a, and 414b and protrudes in the lateral direction (the X direction and/or the Y direction). The molding layers 430a and 430b may be respectively disposed in the regions, protruding in the lateral direction (the X direction and/or the Y direction), of the first integrated circuit devices 411a and 411b and may cover side surfaces of the second to fourth integrated circuit devices 412a, 412b, 413a, 413b, 414a, and 414b. Therefore, the molding layers 430a and 430b may cover sidewalls of the second to fourth integrated circuit devices 412a, 412b, 413a, 413b, 414a, and 414b but may not cover sidewalls of the first integrated circuit devices 411a and 411b.

As illustrated in FIG. 5, the second to fourth integrated circuit devices 412c, 413c, and 414c of the third memory device 410c may be surrounded by the molding layer 430c.

For example, in an embodiment, the molding layers 430a to 430c may include an EMC.

According to an embodiment, the semiconductor package 10 may further include a package molding layer 460 configured to seal the first memory device 410a and the second memory device 410b. In this case, the package molding layer 460 may surround sidewalls of the molding layers 430a and 430b of the first memory device 410a and the second memory device 410b and sidewalls of the first integrated circuit devices 411a and 411b. The package molding layer 460 may be disposed on the interposer redistribution structure 310, and a sidewall of the package molding layer 460 facing the outside may be disposed on the same plane as a sidewall of the interposer redistribution structure 310. The package molding layer 460 may be configured to seal the third memory device 410c, the fourth memory device 410d, the first non-memory device 510a, and the second non-memory device 510b as well as the first memory device 410a and the second memory device 410b, on the interposer 210. The molding layers 430a and 430b may configure an interface differentiated in a relationship with a package molding layer 460 configured to seal the plurality of semiconductor devices 410a to 410d, 510a, and 510b.

For example, the package molding layer 460 may include an EMC.

In some embodiments, the semiconductor package 10 may include a heat dissipation member 470 which covers upper surfaces of the first memory device 410a and the second memory device 410b. The heat dissipation member 470 may include a heat dissipation plate such as a heat slug or a heat sink. In embodiments, the heat dissipation member 470 may surround the first memory device 410a, the second memory device 410b, and the interposer 210, on an upper surface of the package substrate 110.

In some embodiments, the semiconductor package 10 may include a thermal interface material (TIM). The TIM 450 may be disposed between the heat dissipation member 470 and the first memory device 410a and between the heat dissipation member 470 and the second memory device 410b.

According to an embodiment, in a process of mounting the first memory device 410a and the second memory device 410b on the interposer 210 or a process of mounting a semiconductor package device on a mother board, warpage may occur due to a high temperature. The package molding layer 460 disposed between the first memory device 410a and the second memory device 410b spaced apart from each other in the first horizontal direction (the X direction) may be disposed on the interposer 210. In this case, warpage may occur due to a difference of the degree of expansion caused by a mismatch between a coefficient of thermal expansion of the interposer 210 and a coefficient of thermal expansion of the package molding layer 460 disposed between the first memory device 410a and the second memory device 410b.

Particularly, a volume of the package molding layer 460 may be large in a region of the package molding layer 460 disposed between the first memory device 410a and the second memory device 410b, and thus, the package molding layer 460 which is higher in coefficient of thermal expansion than the interposer 210 may much expand due to heat. Therefore, in the interposer 210 of the semiconductor package 10, a thermal expansion difference between a lower region and an upper region may occur, causing warpage of the semiconductor package 10.

According to an embodiment, the semiconductor package 10 may further include a first warpage prevention structure 610a and a second warpage prevention structure 610b disposed on the first surface 210a of the interposer 210. The first warpage prevention structure 610a may be positioned to overlap a part of the first memory device 410a and a part of the second memory device 410b in the vertical direction (Z direction), and the second warpage prevention structure 610b may be positioned to overlap a part of the third memory device 410c and a part of the fourth memory device 410d in the vertical direction (Z direction).

According to an embodiment, the first warpage prevention structure 610a and the second warpage prevention structure 610b may be a single metal layer. In this case, the metal layer is a material having conductivity and may have a relatively high coefficient of thermal expansion. For example, the first warpage prevention structure 610a and the second warpage prevention structure 610b may have a higher coefficient of thermal expansion than the coefficient of thermal expansion of the first molding layer 430a and the second molding layer 430b. Accordingly, when high-temperature heat is applied to the semiconductor package 10, the rate of change in volume due to thermal expansion of the first warpage prevention structure 610a and the second molding layer 430b may be higher than the rate of change in volume due to thermal expansion of the first warpage prevention structure 610a and the second warpage prevention structure 610b.

For example, the first warpage prevention structure 610a and the second warpage prevention structure 610b may include at least one metal among copper (Cu), aluminum (Al), nickel (Ni), silver (Ag), gold (Au), platinum (Pt), tin (Sn), tin (Sn), lead (Pb), titanium (Ti), chromium (Cr), palladium (Pd), indium (In), zinc (Zn), and carbon (C), or an alloy including at least two metals.

Accordingly, as illustrated in FIG. 4, the first warpage prevention structure 610a which has a large coefficient of thermal expansion may be disposed at a lower portion of the interposer 210, and thus, the lower portion of the interposer 210 may expand due to heat, thereby decreasing warpage when mounting the first memory device 410a and the second memory device 410b. A thermal conductance of the first warpage prevention structure 610a may be greater than a thermal conductance of the interposer 210, and thus, heat of the interposer 210 having a good heat dissipation effect may be dissipated to the outside, thereby preventing an internal temperature of the semiconductor package 10 from increasing.

With the same principle, in order to prevent warpage caused by a mismatch between a coefficient of thermal expansion of the interposer 210 and a coefficient of thermal expansion of the package molding layer 460 disposed between the third memory device 410c and the fourth memory device 410d, the second warpage prevention structure 610b may be attached on the first surface 210a of the interposer 210.

Warpage caused by a difference between a coefficient of thermal expansion of the interposer 210 and a coefficient of thermal expansion of the package molding layer 460 may more frequently occur in a region where a volume of the package molding layer 460 is large.

With respect to a plane, the first memory device 410a and the second memory device 410b may be spaced apart from each other in the first horizontal direction (the X direction), and the first memory device 410a may be spaced apart from the first non-memory device 510a in the second horizontal direction (the Y direction). The second memory device 410b may be spaced apart from the second non-memory device 510b in the second horizontal direction (the Y direction). In this case, a separation distance between the first memory device 410a and the second memory device 410b in the first horizontal direction (the X direction) may be defined as a first gap G1, and a separation distance between the first memory device 410a and the first non-memory device 510a in the second horizontal direction (the Y direction) may be defined as a second gap G2 (see, e.g., FIG. 2).

To provide a more detailed description, with respect to a plane, as illustrated in FIG. 2, the first to fourth memory devices 410a to 410d and the first and second non-memory devices 510a and 510b may be disposed on the interposer 210. The first memory device 410a, the first non-memory device 510a, and the third memory device 410c may be aligned with one another in the second horizontal direction (the Y direction), and the second memory device 410b, the second non-memory device 510b, and the fourth memory device 410d may be aligned with one another in the second horizontal direction (the Y direction).

The first memory device 410a may be disposed spaced apart from the second memory device 410b by the first gap G1 in the first horizontal direction (the X direction), the first non-memory device 510a may be disposed spaced apart from the second non-memory device 510b by the first gap G1 in the first horizontal direction (the X direction), and the third memory device 410c may be disposed spaced apart from the fourth memory device 410d by the first gap G1 in the first horizontal direction (the X direction).

A region occupied by the molding layer 460 in the interposer 210 may be greater in the first gap G1 than in the second gap G2, and thus, the first and second warpage prevention structures 610a and 610b may be disposed to overlap the first gap G1 so as to prevent the warpage of the interposer 210. Accordingly, the first warpage prevention structure 610a may be disposed between the first memory device 410a and the second memory device 410b at a lower end of the interposer 210 and may be disposed to vertically overlap (e.g., in the Z direction) the first memory device 410a and the second memory device 410b as illustrated in FIG. 2. The second warpage prevention structure 610b may be disposed between the third memory device 410c and the fourth memory device 410d at the lower end of the interposer 210 and may be disposed to vertically overlap the third memory device 410c and the fourth memory device 410d.

According to an embodiment, a width of the first warpage prevention structure 610a in the first horizontal direction (the X direction) may be defined as a first length L1, and the first length L1 may be greater than the first gap G1 (see, e.g., FIG. 4). The first warpage prevention structure 610a may be disposed to vertically overlap the first memory device 410a and the second memory device 410b, and thus, when all of the first gap G1 overlaps the first warpage prevention structure 610a, the occurrence of warpage in the interposer 210 may be effectively prevented. Likewise, a width of the second warpage prevention structure 610b in the first horizontal direction (the X direction) may be defined as the first length L1.

The first to fourth memory devices 410a to 410d may each be an HBM device which is formed by stacking a plurality of integrated circuit devices, and thus, a height of the semiconductor package 10 in the vertical direction (the Z direction) may be relatively high. Therefore, an aspect ratio of the semiconductor package 10 may be relatively large, and thus, the warpage of the interposer 210 may be more fatal. This fatal warpage may be because, in a case where an aspect ratio of the semiconductor package 10 is large, when the interposer 210 is bent due to warpage, a scale by which all of the semiconductor package 10 is bent increases. Accordingly, when the first warpage prevention structure 610a and the second warpage prevention structure 610b are disposed between the first memory device 410a and the second memory device 410b and between the third memory device 410c and the fourth memory device 410d which are HBM devices, the first warpage prevention structure 610a and the second warpage prevention structure 610b may be more effective.

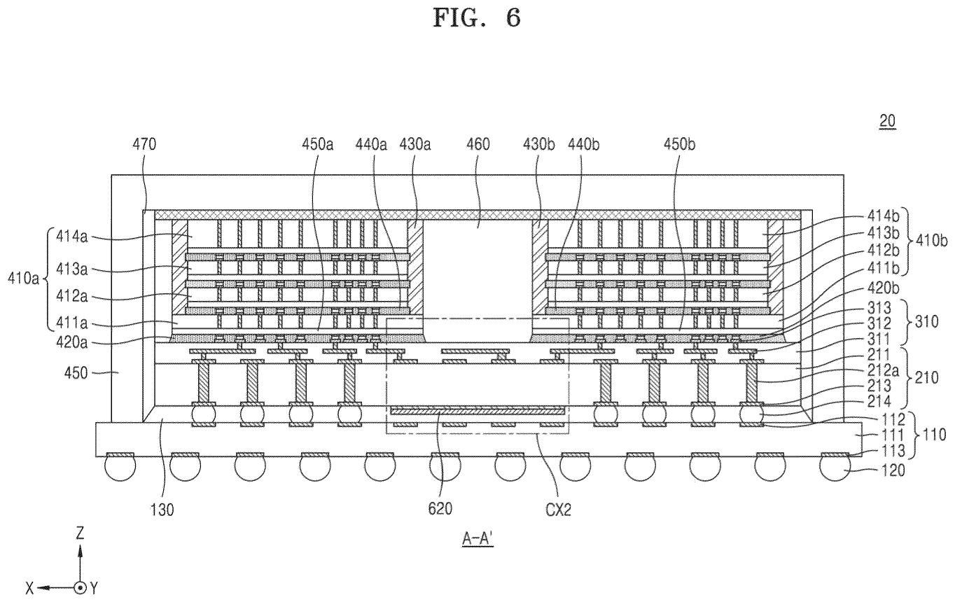

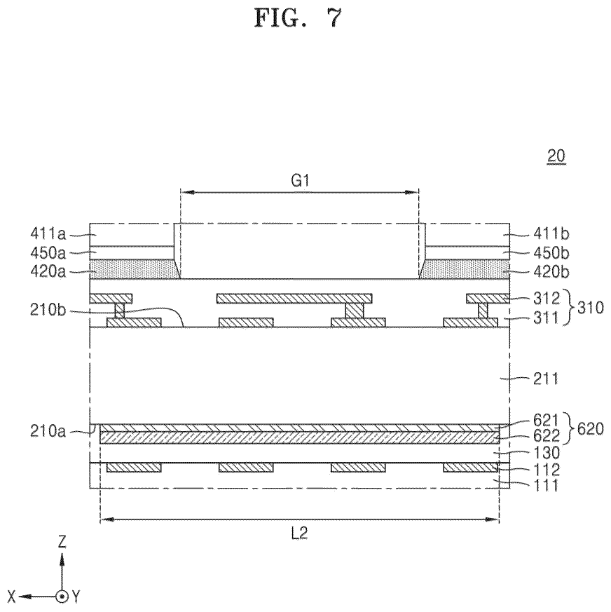

FIG. 6 is a cross-sectional view of a semiconductor package 20 according to an embodiment, and FIG. 7 is an enlarged view of a region CX2 of FIG. 6.

Except for a warpage prevention structure 620, the semiconductor package 20 illustrated in FIGS. 6 and 7 may be almost the same as or similar to the semiconductor package 10 illustrated in FIGS. 1 to 4. Therefore, the descriptions of elements given above with FIGS. 1 to 4 are omitted or will be briefly given for conciseness.

Referring to FIGS. 6 and 7, the semiconductor package 20 according to an embodiment may include a warpage prevention structure 620 which is disposed on a first surface 210a of an interposer 210, is disposed between a first semiconductor device 410a and a second semiconductor device 410b with respect to a horizontal plane, and vertically overlaps the first semiconductor device 410a and the second semiconductor device 410b.

In this case, the warpage prevention structure 620 illustrated in FIGS. 6 and 7 may include two layers, unlike the warpage prevention structures 610a and 610b illustrated in FIGS. 1 to 4. The warpage prevention structure 620 may include an adhesive film attached on a second surface 210b of the interposer 210 and a silicon dummy 622 attached along a lower surface of the adhesive film 621.

An upper surface and the lower surface of the adhesive film 621 may have an area corresponding to a lower surface of the silicon dummy 622. The adhesive film 621 may vertically overlap the silicon dummy 622 in a lateral direction (an X direction and/or a Y direction). The silicon dummy 622 may include silicon, and the silicon may be used instead of a copper tape. The silicon may effectively dissipate heat, transferred from a plurality of semiconductor devices 410a and 410b to the interposer 210, to the outside, and thus, may improve a heat dissipation effect.

Because the adhesive film 621 including an adhesive material is attached on the second surface 210b of the interposer 210, the adhesive film 621 may fix the interposer 210 so that the interposer 210 is not bent due to warpage caused by a difference between a coefficient of thermal expansion of the interposer 210 and a coefficient of thermal expansion of a package molding layer 460.

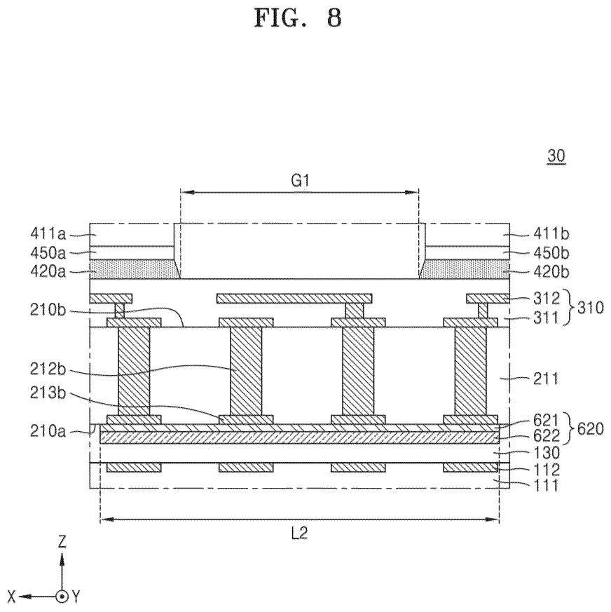

FIG. 8 is an enlarged view of a semiconductor package 30 according to an embodiment.

Except for a structure of an interposer 210, the semiconductor package 30 illustrated in FIG. 8 may be almost the same as or similar to the semiconductor package 20 illustrated in FIGS. 6 and 7. Therefore, the descriptions of elements given above with FIGS. 6 and 7 are omitted or will be briefly given for conciseness.

Referring to FIG. 8, an interposer 210 of the semiconductor package 30 may further include a plurality of second through vias 212b passing through an interposer substrate 211 and a plurality of second interposer pads 213b disposed under the second through vias 212b. The second through vias 212b may be defined as a through via which overlaps a warpage prevention structure 620 in a vertical direction (a Z direction), and the second interposer pads 213b may be defined as a pad which overlaps the warpage prevention structure 620 in the vertical direction (the Z direction). In some embodiments, a first through via 212a may be defined as a through via which surrounds the second through via 212b in the interposer substrate 211 and does not overlap the warpage prevention structure 620 in the vertical direction (the Z direction). In some embodiments, a first interposer pad 213 may be defined as a pad which surrounds the second interposer pad 213b in the interposer substrate 211 and does not overlap the warpage prevention structure 620 in the vertical direction (the Z direction).

According to an embodiment, an adhesive film 621 and a silicon dummy 622 each configuring the warpage prevention structure 620 may include an insulating material. Accordingly, even when the adhesive film 621 physically contacts the second interposer pads 213b, the second through vias 212b may be electrically insulated from the adhesive film 621. Therefore, in a case in which the interposer 210 is manufactured, the second through vias 212b and the second interposer pads 213b may not be electrically connected to the warpage prevention structure 620, so that a through via does not provide electric connection in a region overlapping the warpage prevention structure 620. For example, in a case where the warpage prevention structure 620 is electrically connected to a plurality of second through vias 212b and a plurality of second interposer pads 213b, interference may occur in an electrical signal, but the warpage prevention structure 620 of the semiconductor package 30 according to an embodiment may address such a problem.

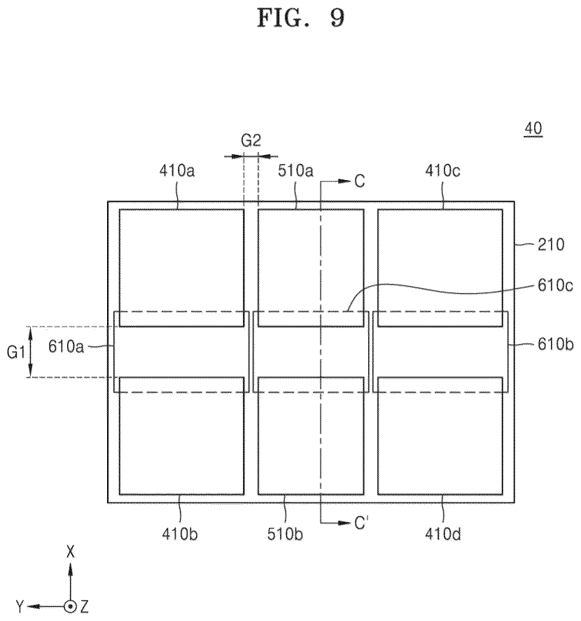

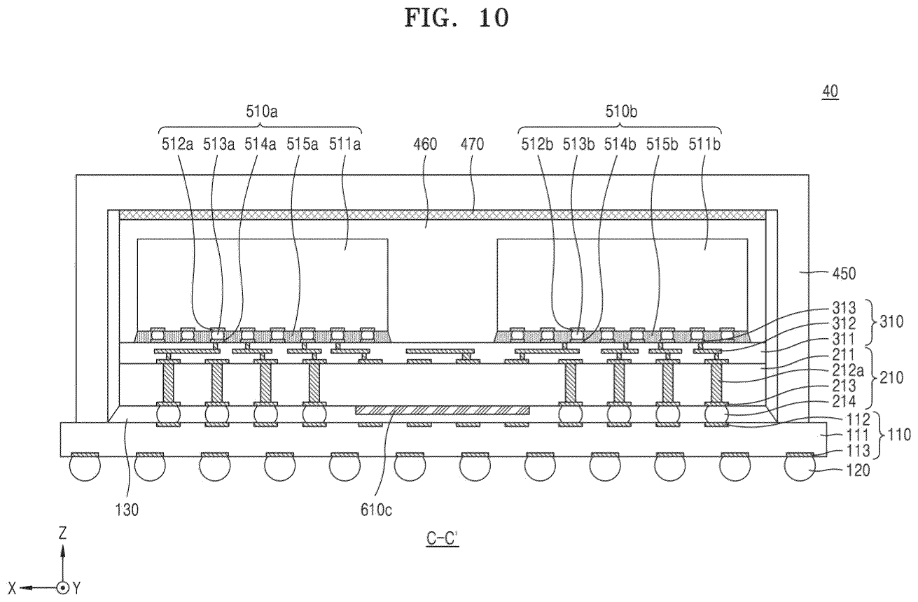

FIG. 9 is a plan view of a semiconductor package 40 according to an embodiment, and FIG. 10 is a cross-sectional view taken along line C-C′ of FIG. 9.

Except for a third warpage prevention structure 610c disposed between a first non-memory device 510a and a second non-memory device 510b with respect to a plane, the semiconductor package 40 illustrated in FIGS. 9 and 10 may be almost the same as or similar to the semiconductor package 10 illustrated in FIGS. 1 to 4. Therefore, the descriptions of elements given above with FIGS. 1 to 4 are omitted or will be briefly given for conciseness.

Referring to FIGS. 9 and 10, the semiconductor package 40 according to an embodiment may include a third warpage prevention structure 610c which is disposed on a first surface 210a of an interposer 210, is disposed between a first non-memory device 510a and a second non-memory device 510b with respect to a horizontal plane, and vertically overlaps the first non-memory device 510a and the second non-memory device 510b.

The first non-memory device 510a and the second non-memory device 510b may include the same configuration as the configuration of the first non-memory device 510a illustrated in FIG. 5. Each of the first non-memory device 510a and the second non-memory device 510b may include respectively chip bodies 511a and 511b, chip pads 512a and 512b, chip connection terminals 513a and 513b, and third under-fills 514a and 514b. The chip bodies 511a and 511b, chip pads 512a and 512b, chip connection terminals 513a and 513b, and third under-fills 514a and 514b may be the same as the chip body 511a, the chip pad 512a, the chip connection terminal 513a, and the third under-fill 514a described above with reference to FIG. 5, and thus, their detailed descriptions are omitted for conciseness.

According to an embodiment, the first non-memory device 510a and the second non-memory device 510b may be arranged spaced apart from each other by a first gap G1 in a first horizontal direction (an X direction). In this case, the third warpage prevention structure 610c may be disposed between the first non-memory device 510a and the second non-memory device 510b, on the first surface 210a of the interposer 210, thereby preventing the occurrence of warpage caused by a mismatch between a coefficient of thermal expansion of the interposer 210 and a coefficient of thermal expansion of a package molding layer 460.

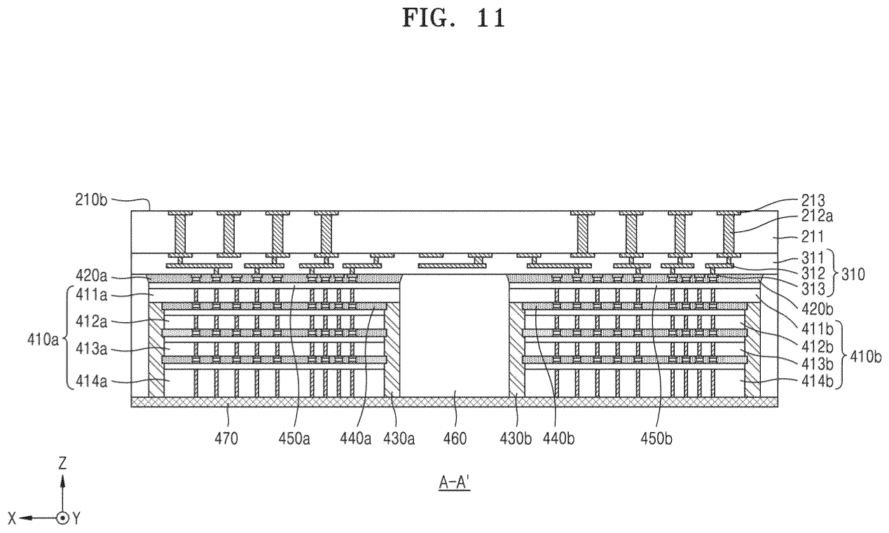

FIGS. 11 to 13 are cross-sectional views illustrating in sequence a method of manufacturing a semiconductor package, according to an embodiment.

Referring to FIG. 11, a second surface 210b of an interposer 210 may be disposed upward in a vertical direction (a Z direction). In this case, although not shown in detail in the drawing, a carrier substrate may be disposed on a heat dissipation member 470 to enable a first memory device 410a and a second memory device 410b each mounted on the interposer 210 to be reversed. A plurality of interposer pads 213 may be exposed at the second surface 210b of an interposer substrate 211 of the interposer 210.

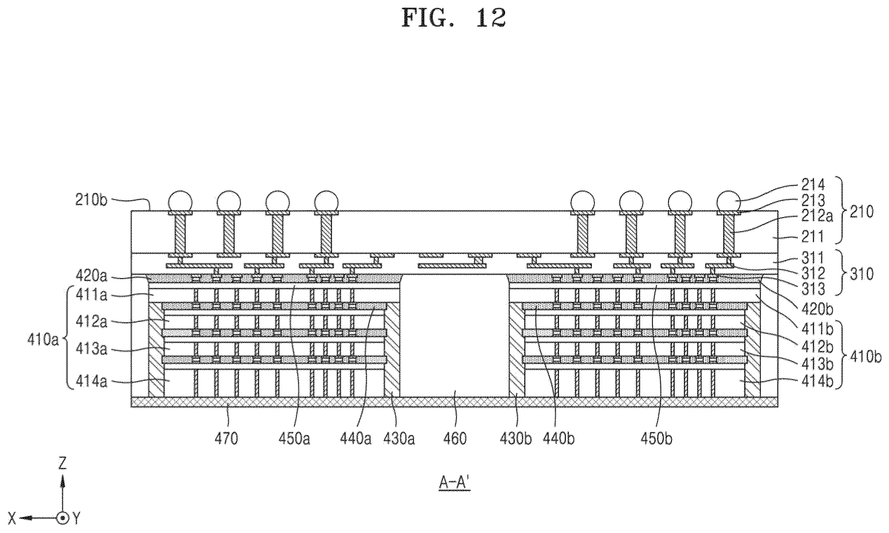

Referring to FIG. 12, interposer connection terminals 214 may be attached on the plurality of interposer pads 213 exposed at the second surface 210b of the interposer substrate 211. In this case, a process of attaching the interposer connection terminals 214 may be a reflow process.

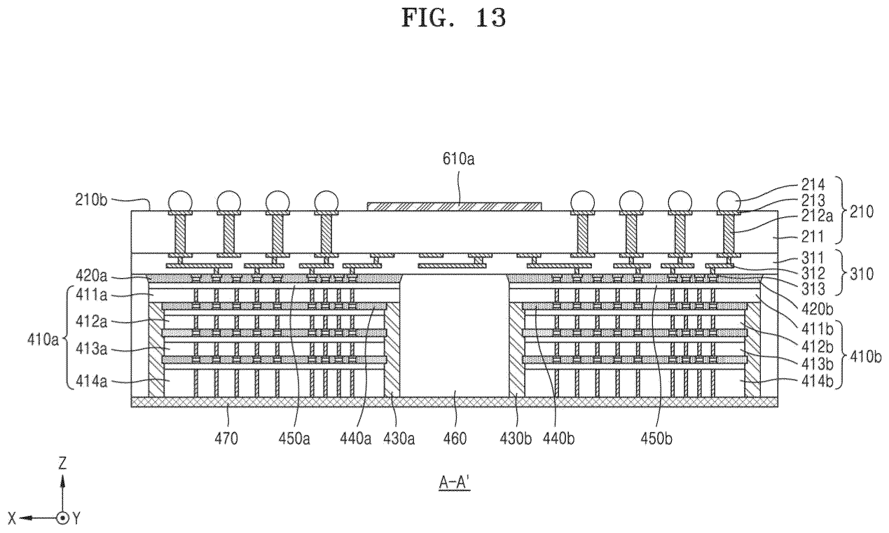

Referring to FIG. 13, a first warpage prevention structure 610a may be attached on the second surface 210b of the interposer 210. In this case, the first warpage prevention structure 610a may be attached on the second surface 210b of the interposer 210 not to overlap the through vias 212a. The first warpage prevention structure 610a may be formed to extend along the second surface 210b of the interposer 210.

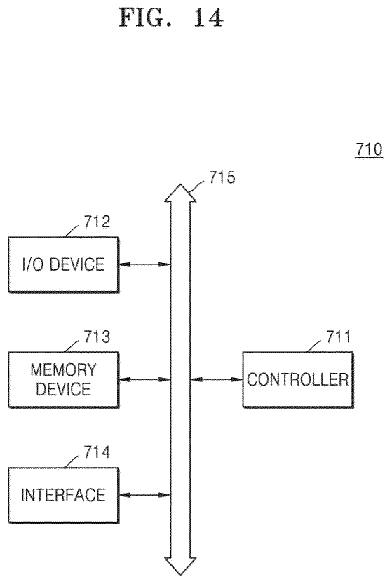

FIG. 14 is a schematic block diagram illustrating an example of a memory system 710 including a semiconductor package, according to an embodiment.

In detail, the memory system 710 may be applied to personal digital assistants (PDAs), portable computers, web tablets, wireless phones, mobile phones, digital music players, memory cards, or all devices capable of transmitting and/or receiving information in a wireless environment.

The memory system 710 may include a controller 711, an I/O device 712, a memory device 713, an interface 714, and a bus 715. The memory device 713 and the interface 714 may communicate with each other through the bus 715.

The controller 711 may include at least one microprocessor, a digital signal processor, a microcontroller, or other process devices similar thereto. The memory device 713 may be used to store program code executed by the controller 711. The program code may include one or more commands executed by the controller 711. The I/O device 712 may receive data or a signal from the outside of the memory system 710, or may output data or a signal to the outside of the memory system 710. For example, the I/O device 712 may include a keyboard, a keypad, and/or a display device.

The memory device 713 and the controller 711 may include a semiconductor package PK1-PK2 according to an embodiment. The interface 714 may transmit data to a communication network, or may receive data from the communication network.

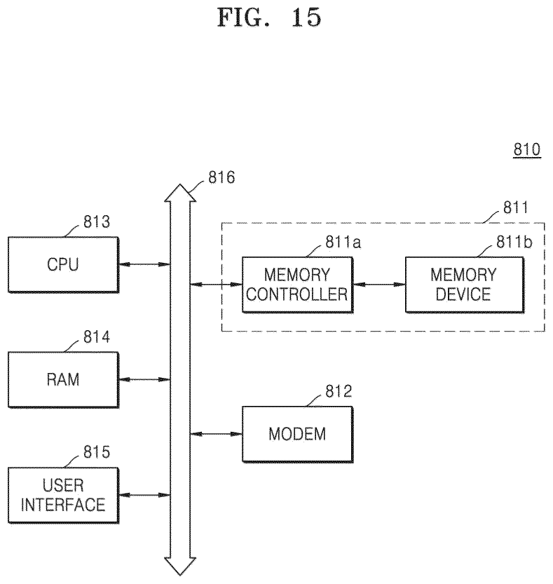

FIG. 15 is a schematic block diagram illustrating an example of an information processing system 810 including a semiconductor package, according to an embodiment.

In detail, the information processing system 810 may be used in mobile devices or desktop computers. The information processing system 810 may include a memory system 811 including a memory controller 811a and a memory device 811b.

The information processing system 810 may include a modulator and demodulator (modem) 812, a CPU 813, random access memory (RAM) 814, and a user interface 815, which are electrically connected to a system bus 816. Data obtained through processing by the CPU 813 or data input from the outside may be stored in the memory system 811.

The memory system 811 including the memory controller 811a and the memory device 811b, the modem 812, and the CPU 813 may include a semiconductor package (PK1-PK2 of FIGS. 1 and 6) according to an embodiment.

The memory system 811 may be configured with a solid state drive (SSD), and in this case, the information processing system 810 may stably store massive data in the memory system 811. The memory system 811 may decrease resources consumed in error correction and may thus provide a high-speed data exchange function to the information processing system 810. Although not shown, the information processing system 810 may further include an application chipset, a camera image signal processor (ISP), and an I/O device.

Hereinabove, various embodiments have been described in the drawings and the specification. Various embodiments have been described by using the terms described herein, but these terms have been used merely for describing the various embodiments and have not been used for limiting a meaning or limiting the scope of the present disclosure defined in the following claims. Therefore, it may be understood by those of ordinary skill in the art that various modifications and other equivalent embodiments may be implemented from the various embodiments described herein. Accordingly, the spirit and scope of the present disclosure may be defined based on the spirit and scope of the following claims.

While various embodiments have been particularly shown and described with reference to the drawings, it will be understood that various changes in form and details may be made therein without departing from the spirit and scope of the following claims.

What is claimed is:

1. A semiconductor package comprising:
a package substrate;
an interposer disposed on the package substrate, the interposer including a first surface and a second surface opposite to the first surface;
a first semiconductor device mounted on the second surface of the interposer;
a second semiconductor device disposed on the second surface and spaced apart from the first semiconductor device in a first horizontal direction that is parallel to the second surface; and
a warpage prevention structure disposed on the first surface of the interposer at a position on the first surface that corresponds to a position between the first semiconductor device and the second semiconductor device on the second surface of the interposer and that vertically overlaps the first semiconductor device and the second semiconductor device.

2. The semiconductor package of claim 1, wherein the warpage prevention structure includes a copper film.

3. The semiconductor package of claim 1, wherein the warpage prevention structure comprises:
an adhesive film attached to the first surface of the interposer; and
a silicon dummy attached along a lower surface of the adhesive film.

4. The semiconductor package of claim 3, wherein the interposer comprises:
an interposer substrate; and
a plurality of interposer through vias passing through the interposer substrate, and
a portion of each of the plurality of interposer through vias overlaps the warpage prevention structure.

5. The semiconductor package of claim 1, further comprising a plurality of interposer connection terminals disposed on the first surface of the interposer,
wherein the plurality of interposer connection terminals surround the warpage prevention structure.

6. The semiconductor package of claim 5, further comprising an under-fill material layer that buries the plurality of interposer connection terminals and the warpage prevention structure.

7. The semiconductor package of claim 1, wherein each of the first semiconductor device and the second semiconductor device comprises:
a high bandwidth memory (HBM) control die including a plurality of through vias; and
a plurality of dynamic random-access memory (DRAM) dies stacked on the HBM control die.

8. The semiconductor package of claim 1, further comprising a third semiconductor device disposed on the second surface of the interposer and spaced apart from the first semiconductor device in a second horizontal direction that is parallel to the second surface and that is perpendicular to the first horizontal direction, the third semiconductor device including a system on chip.

9. The semiconductor package of claim 1, wherein the warpage prevention structure is spaced apart from the package substrate in a vertical direction perpendicular to the second surface of the interposer.

10. The semiconductor package of claim 1, wherein a coefficient of thermal expansion of the warpage prevention structure is higher than a coefficient of thermal expansion of the interposer.

11. The semiconductor package of claim 1, wherein a thermal conductance of the warpage prevention structure is greater than a thermal conductance of the interposer.

12. A semiconductor package comprising:
a package substrate;
an interposer disposed on the package substrate, the interposer including a first surface and a second surface opposite to the first surface;
a pair of first memory devices mounted on the second surface of the interposer and disposed spaced apart from each other in a first horizontal direction that is parallel to the second surface;
a pair of non-memory devices disposed spaced apart from the pair of first memory devices in a second horizontal direction perpendicular to the first horizontal direction; and
a first warpage prevention structure disposed on the first surface of the interposer at a position that corresponds to a position between the pair of first memory devices on the second surface of the interposer and that vertically overlaps each of the pair of first memory devices.

13. The semiconductor package of claim 12, wherein each of the pair of first memory devices comprises:
a high bandwidth memory (HBM) control die including a plurality of through vias; and
a plurality of dynamic random-access memory (DRAM) dies stacked on the HBM control die.

14. The semiconductor package of claim 12, further comprising a package molding layer that seals the pair of first memory devices and the pair of non-memory devices,
wherein the package molding layer overlaps the first warpage prevention structure.

15. The semiconductor package of claim 12, further comprising a pair of second memory devices mounted on the second surface of the interposer and disposed spaced apart from the pair of first memory devices with the pair of non-memory devices therebetween in the second horizontal direction that is parallel to the second surface and perpendicular to the first horizontal direction.

16. The semiconductor package of claim 15, further comprising a second warpage prevention structure disposed on the first surface of the interposer at a position that corresponds to a position between the pair of second memory devices on the second surface of the interposer and that vertically overlaps each of the pair of second memory devices.

17. The semiconductor package of claim 12, wherein the pair of first memory devices are disposed spaced apart from each other by a first gap in the first horizontal direction,
the pair of first memory devices and the pair of non-memory devices are disposed spaced apart from each other by a second gap in the second horizontal direction, and
the first gap is greater than the second gap.

18. The semiconductor package of claim 12, further comprising a third warpage prevention structure disposed on the first surface of the interposer at a position that corresponds to a position between the pair of non-memory devices on the second surface of the interposer and that vertically overlaps each of the pair of non-memory devices with respect to a horizontal plane.

19. A semiconductor package comprising:
a package substrate;
an interposer including an interposer substrate and a plurality of interposer through vias passing through the interposer substrate, the interposer substrate being disposed on the package substrate, and the interposer including a first surface and a second surface opposite to the first surface;
a plurality of interposer connection terminals disposed on the first surface of the interposer;
a pair of first memory devices mounted on the second surface of the interposer and disposed spaced apart from each other in a first horizontal direction that is parallel to the second surface;
a pair of non-memory devices mounted on the second surface of the interposer and disposed spaced apart from the pair of first memory devices in a second horizontal direction perpendicular to the first horizontal direction;
a pair of second memory devices mounted on the second surface of the interposer and disposed spaced apart from the pair of first memory devices with the pair of non-memory devices therebetween in the second horizontal direction;
a package molding layer that seals the pair of first memory devices, the pair of non-memory devices, and the pair of second memory devices;
a first warpage prevention structure disposed on the first surface of the interposer at a position on the first surface that corresponds to a position between the pair of first memory devices on the second surface of the interposer and that vertically overlaps each of the pair of first memory devices and the package molding layer; and
a second warpage prevention structure disposed on the first surface of the interposer at a position on the first surface that corresponds to a position between the pair of second memory devices on the second surface of the interposer and that vertically overlaps each of the pair of second memory devices and the package molding layer.

20. The semiconductor package of claim 19, wherein each of the pair of first memory devices and the pair of second memory devices comprises:
a high bandwidth memory (HBM) control die including a plurality of through vias; and
a plurality of dynamic random-access memory (DRAM) dies stacked on the HBM control die.
